(19) United States
(12) Patent Application Publication
(10) Pub. No.: US 2004/0232448 A1
(43) Pub. Date: Nov. 25, 2004

(54) Layout style in the interface between input/output (I/O) cell and bond pad

(75) Inventors: Tsung-Hsin Yu, Kaohsiung City (TW); Hsien-Chin Chen, Hsin Chu (TW)

Correspondence Address: STEPHEN B. ACKERMAN, 28 DAVIS AVENUE, POUGHKEEPSIE, NY, 12603, US

(73) Assignee: Taiwan Semiconductor Manufacturing Co.

(21) Appl. No.: 10/444,873

(22) Filed: May 23, 2003

(51) Int. Cl. H01L 27/10; H01L 21/82; H01L 21/44

(52) U.S. Cl. 257/203; 438/128; 438/129; 257/208; 257/211; 257/758; 438/118

(57) ABSTRACT

A layout design for I/O cell area/bond pad area interfaces, and a method of form the same, comprising: a substrate having an I/O cell area and a bond pad area separated by a trench area; and multiple metal lines over the substrate. The multiple metal lines including a lowermost metal line, lower intermediate metal lines, upper intermediate metal lines and an uppermost metal line, wherein at least one of the upper intermediate metal lines includes a respective extension portion, that is contiguous with, or separate therefrom, extending into at least through the trench area.

### FIELD OF THE INVENTION

The present invention relates generally to semiconductor fabrication and more specifically to layout designs for I/O cell/bond pad interfaces.

### BACKGROUND OF THE INVENTION

As processes develop, the number of metal layout is increased from 5 in 0.25 μm to 9 in 90 nm. It is possible for cracks to occur within the oxide layer between the I/o cell side and the bond pad side.

U.S. Pat. No. 5,401,989 to Kikuchi describes a layout of a cell region and I/O region.

U.S. Pat. No. 6,326,693 B1 to Minmoto et al. describes a layout for core and power lines.

U.S. Pat. No. 6,157,052 to Kuge et al. describes a layout for an integrated circuit having three wiring layers.

U.S. Pat. No. 6,242,767 B1 to How et al. describes an ASIC routing architecture layout for four layers.

### SUMMARY OF THE INVENTION

Accordingly, it is an object of one or more embodiments of the present invention to provide an I/O cell/bond pad interface layout design and a method of forming same.

Other objects will appear hereinafter.

It has now been discovered that the above and other objects of the present invention may be accomplished in the following manner. Specifically, a layout design for I/O cell area/bond pad area interfaces comprises a substrate having an I/O cell area and a bond pad area separated by a trench area; and multiple metal lines over the substrate. The multiple metal lines including a lowermost metal line, lower intermediate metal lines, upper intermediate metal lines and an uppermost metal line, wherein at least one of the upper intermediate metal lines includes a respective extension portion, that is contiguous with, or separate therefrom, extending into at least through the trench area. A method of forming the layout design for I/O cell area/bond pad area interfaces.

### BRIEF DESCRIPTION OF THE DRAWINGS

The present invention will be more clearly understood from the following description taken in conjunction with the accompanying drawings in which like reference numerals designate similar or corresponding elements, regions and portions and in which:

FIG. 1 schematically illustrates a structure known to the inventors.

FIGS. 2 to 4 schematically illustrates a preferred embodiment of the present invention.

### DETAILED DESCRIPTION OF THE PREFERRED EMBODIMENT

Process and Structure Known to the Inventors—Not to be Considered Prior Art

The following is a process and structure known to the inventors and is not to be considered as prior art for the purposes of the instant invention.

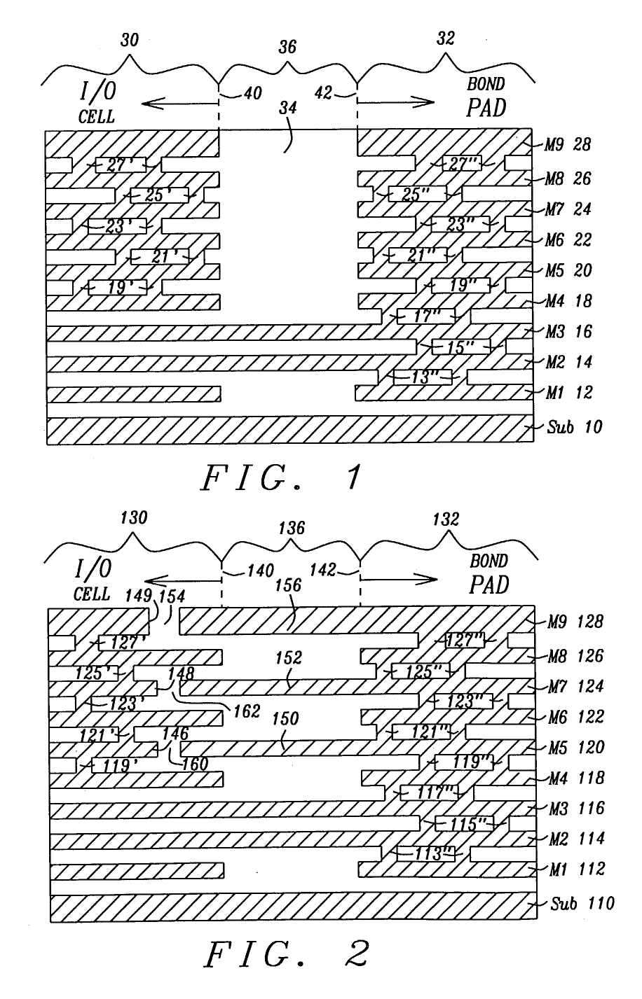

As shown in FIG. 1, the old layout design with nine (9) metal layers (M1 12, M2 14, M3 16, M4 18, M5 20, M6 22, M7 24, M8 26 and M9 28), for example, formed over substrate 10 all of the nine metal layers are connected together by via structures 13″, 15″, 17″, 19″, 21″, 23″, 25″, 27″, respectively, in the bond pad side 32 and from four to nine of the nine metal layers, i.e. M4 18 through M9 28 as shown in FIG. 1, for example, are connected together by via structures 19′, 21′, 23′, 25′, 27′, respectively, to form a power line in the I/O cell side 30. Only metal 2 (M2 14) and metal 3 (M3 16) are connected from the bond pad side 32 into the I/O cell side 30.

Substrate 10 is preferably includes a semiconductor wafer or substrate, active and passive devices formed within the wafer, conductive layers and dielectric layers (e.g., inter-poly oxide (IPO), intermetal dielectric (IMD), etc.) formed over the wafer surface. The term “semiconductor structure” is meant to include devices formed within a semiconductor wafer and the layers overlying the wafer. Depending upon the functionality of the I/O cell, substrate 10 may be electrically connected to the M1 12 metal layer.

Respective intermetal dielectric (IMD) layers fill the interstitial spaces between the metal layers M1 12 through M9 28, throughout the trench area 36 and between the first metal layer M1 12 and the substrate 10.

Based upon this layout scheme/design, the four to nine metal layers, i.e. M4 18 through M9 28 as shown in FIG. 1, for example, in both the bond pad and I/O cell sides 32, 30 are self-aligned at respective aligned edges 42, 40. Therefore, a large and deep oxide gap 34 will appear within trench area 36. This causes a reliability issue because the oxide gap may crack. For example, a crack in the oxide gap at the seventh inter-metal dielectric (IMD) layer has been found in a 90 nm test chip.

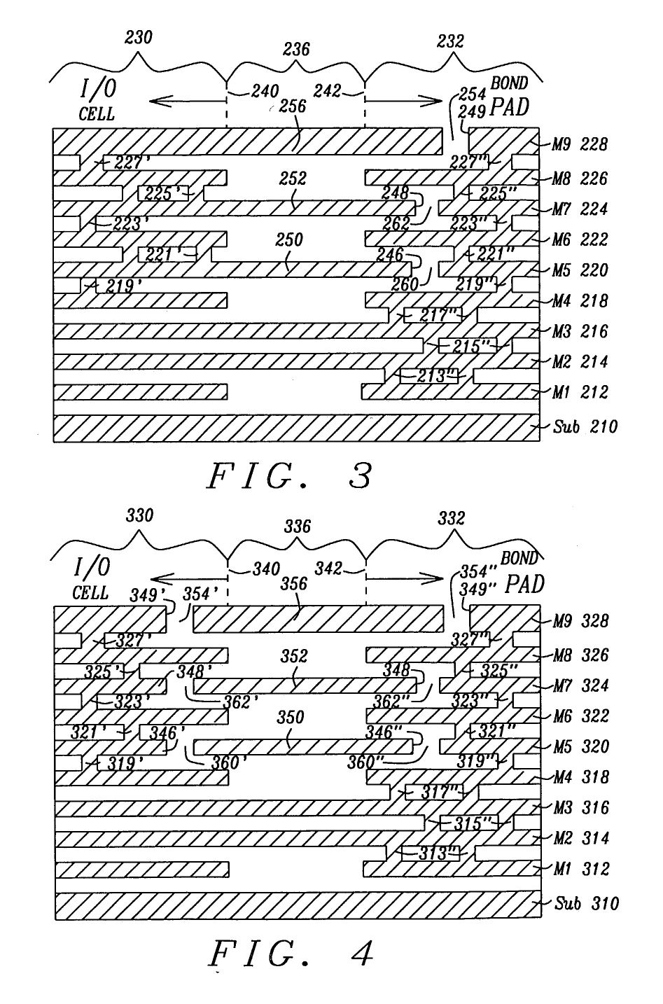

Common to all Embodiments—FIGS. 2 Through 4

It is noted that more than nine metal layers may be formed and that nine metal layers are shown and described herein as an example only in accordance with the teachings of the embodiments of the present invention. In the embodiments of the present invention: the metal layers are preferably comprised of copper, aluminum, silver or gold; and the IMD layers are preferably comprised of oxide or silicon oxide and more preferably oxide.

First Embodiment; Bond Pad Side 132 Metal Extensions 150, 152, 156—FIG. 2

As shown in FIG. 2, in the first embodiment layout design with nine (9) metal layers (M1 112, M2 114, M3 116, M4 118, M5 120, M6 122, M7 124, M8 126 and M9 128), for example, formed over substrate 110 all of the nine metal layers are connected together by via structures 113″, 115″, 117″, 119″, 121″, 123″, 125″, 127″, respectively, in the bond pad side 132 and from four to nine of the nine metal layers, i.e. M4 118 through M9 128 as shown in FIG. 2, for example, are connected together by via structures 119′, 121′, 123′, 125′, 127′, respectively, to form a power line in the 110 cell side 130. Preferably, only metal 2 (M2 114) and metal 3 (M3 116) are connected from the bond pad side 132 into the I/O cell side 130.

Substrate 110 is preferably includes a semiconductor wafer or substrate, active and passive devices formed within the wafer, conductive layers and dielectric layers (e.g., inter-poly oxide (IPO), intermetal dielectric (IMD), etc.) formed over the wafer surface. The term “semiconductor structure” is meant to include devices formed within a semiconductor wafer and the layers overlying the wafer. Depending upon the functionality of the I/O cell, substrate 110 may be electrically connected to the M1 112 metal layer.

Respective intermetal dielectric (IMD) layers fill the interstitial spaces between the metal layers M1 112 through M9 128, throughout the trench area 136 and between the first metal layer M1 112 and the substrate 110.

In the first embodiment layout scheme/design, at least one of the lower metal layers M4 118 to M8 128, i.e., e.g. metal layers M5 120 and M7 124 and the uppermost metal layer, i.e., e.g. metal layer M9 128, in the I/O cell side 130 are backed away from the alignment edge 140 (as at 146, 148 and 149, respectively) and the corresponding metal layers M5 120, M7 124 and the upper most metal layer M9 128 in the bond pad side 132 extend (as at 150, 152, 156 respectively) through the trench area 136 into the I/O cell side 130 and past I/O cell alignment edge 140 and approach, but do not contact, the backed-away metal layers M5 120, M7 124 and M9 128 in the I/O cell side 130 as shown in FIG. 2 to form a “sandwich” or interlocking array of metal layers. Respective openings 160, 162, 154 exist between the backed-away metal layers M5 120, M7 124 and M9 128 in the I/O cell side 130 and the extensions 150, 152, 156 of the corresponding metal layers M5 120, M7 124 and M9 128 in the bond pad side 132.

Although opening 154 in M9 128 metal layer need not be aligned with the lower openings 160, 162, it usually is aligned for layout convenience.

Since metal layer extensions 150, 152, 156 from metal layers M5 120, M7 124 and M9 128 in the example through the trench area 136 and into the I/O cell area 130, the oxide within the trench area 136 is prevented from cracking.

Second Embodiment; I/O Cell Side 230 Metal Extensions 250, 252, 256—FIG. 3

As shown in FIG. 3, in the second embodiment layout design with nine (9) metal layers (M1 212, M2 214, M3 216, M4 218, M5 220, M6 222, M7 224, M8 226 and M9 228), for example, formed over substrate 210 all of the nine metal layers are connected together by via structures 213″, 215″, 217″, 219″, 221″, 223″, 225″, 227″, respectively, in the bond pad side 232 and from four to nine of the nine metal layers, i.e. M4 218 through M9 228 as shown in FIG. 3, for example, are connected together by via structures 219′, 221′, 223′, 225′, 227′, respectively, to form a power line in the I/O cell side 230. Preferably, only metal 2 (M2 214) and metal 3 (M3 216) are connected from the bond pad side 232 into the I/O cell side 230.

Substrate 210 is preferably includes a semiconductor wafer or substrate, active and passive devices formed within the wafer, conductive layers and dielectric layers (e.g., inter-poly oxide (IPO), intermetal dielectric (IMD), etc.) formed over the wafer surface. The term “semiconductor structure” is meant to include devices formed within a semiconductor wafer and the layers overlying the wafer. Depending upon the functionality of the I/O cell, substrate 210 may be electrically connected to the M1 212 metal layer.

Respective intermetal dielectric (IMD) layers fill the interstitial spaces between the metal layers M1 212 through M9 228, throughout the trench area 336 and between the first metal layer M1 212 and the substrate 210.

In the second embodiment layout scheme/design, at least one of the lower metal layers M4 218 to M8 228, i.e., e.g. metal layers M5 220 and M7 224 and the uppermost metal layer, i.e., e.g. metal layer M9 228, in the bond pad side 232 are backed away from the alignment edge 242 (as at 246, 248 and 249, respectively) and the corresponding metal layers M5 220, M7 224 and the uppermost metal layer M9 228 in the I/O cell side 230 extend (as at 250, 252, 256 respectively) through the trench area 236 into the bond pad side 232 and past bond pad alignment edge 242 and approach, but do not contact, the backed-away metal layers M5 220, M7 224 and M9 228 in the bond pad side 232 as shown in FIG. 3 to form a “sandwich” or interlocking array of metal layers. Respective openings 260, 262, 254 exist between the backed-away metal layers M5 220, M7 224 and M9 228 in the bond pad side 232 and the extensions 250, 252, 256 of the corresponding metal layers M5 220, M7 224 and M9 228 in the I/O cell side 230.

Although opening 254 in M9 228 metal layer need not be aligned with the lower openings 260, 262, it usually is aligned for layout convenience.

Since metal layer extensions 250, 252, 256 from metal layers M5 220, M7 224 and M9 228 in the example through the trench area 236 and into the bond pad area 232, the oxide within the trench area 236 is prevented from cracking.

Third Embodiment; Floating Metal Extensions 350, 352, 356—FIG. 4

As shown in FIG. 4, in the third embodiment layout design with nine (9) metal layers (M1 312, M2 314, M3 316, M4 318, M5 320, M6 322, M7 324, M8 326 and M9 328), for example, formed over substrate 310 all of the nine metal layers are connected together by via structures 313″, 315″, 317″, 319″, 321″, 323″, 325″, 327″, respectively, in the bond pad side 332 and from four to nine of the nine metal layers, i.e. M4 318 through M9 328 as shown in FIG. 4, for example, are connected together by via structures 319′, 321′, 323′, 325′, 327′, respectively, to form a power line in the I/O cell side 330. Preferably, only metal 2 (M2 314) and metal 3 (M3 316) are connected from the bond pad side 332 into the I/O cell side 330.

Substrate 310 is preferably includes a semiconductor wafer or substrate, active and passive devices formed within the wafer, conductive layers and dielectric layers (e.g., inter-poly oxide (IPO), intermetal dielectric (IMD), etc.) formed over the wafer surface. The term “semiconductor structure” is meant to include devices formed within a semiconductor wafer and the layers overlying the wafer. Depending upon the functionality of the I/O cell, substrate 310 may be electrically connected to the M1 312 metal layer.

Respective intermetal dielectric (IMD) layers fill the interstitial spaces between the metal layers M1 312 through M9 328, throughout the trench area 336 and between the first metal layer M1 312 and the substrate 310.

In the third embodiment layout scheme/design, at least one of the lower metal layers M4 318 to M8 328, i.e., e.g. metal layers M5 320 and M7 324 and the uppermost metal layer, i.e., e.g. metal layer M9 228, in the bond pad side 232 are backed away from both of the alignment edges 340, 342 (as at 346′, 346″, 348′, 248″, 349′ and 349″, respectively) and respective floating metal extensions 350, 352, 356 are formed between the corresponding backed-away metal layers M5 320, M7 324 and the uppermost metal layer M9 328. Floating metal extensions 350, 352, 356 extend within the trench area 336 and preferably into both the I/O cell side 330 past I/O alignment edge 340 and the bond pad side 332 past bond pad alignment edge 342 and approach, but do not contact, the backed-away metal layers M5 320, M7 324 and M9 328 in the I/O cell side 330 and the bond pad side 332 as shown in FIG. 4 to form a “sandwich” or interlocking array of metal layers. Respective openings 260′, 260″, 262′, 262″, 254′, 254″ exist between the backed-away metal layers M5 320, M7 324 and M9 328 in the I/O cell and bond pad sides 330, 332 and the floating extensions 350, 352, 356 of the corresponding metal layers M5 320, M7 324 and M9 328.

Although opening 254′; 254″ in M9 328 metal layer need not be aligned with the lower openings 360′; 360″, 362′; 362″, it usually is aligned for layout convenience.

Since floating metal layer extensions 350, 352, 356 of metal layers M5 320, M7 324 and M9 328 in the example extend within the trench area 336 and into the I/O cell and bond pad areas 330, 332, the oxide within the trench area 336 is prevented from cracking.

Further Embodiments

It is noted by one skilled in the art that the teachings of the present invention are not limited to the specific number, or position, of metal lines as shown in the Figures either:

extending from the bond pad side into the I/O cell side;

extending from the I/O cell side into the bond pad side; or

floating metal extensions extending from the I/O cell side into the bond pad side.

It is further possible for one skilled in the art to employ the teachings of the present invention to have ‘fully floating’ metal extensions extending between the I/O cell side and the bond pad side.

Advantages of the Present Invention

The advantages of one or more embodiments of the present invention include preventing oxide within the trench area from cracking.

While particular embodiments of the present invention have been illustrated and described, it is not intended to limit the invention, except as defined by the following claims.

We claim:

1. A method of forming a layout design for I/O cell area/bond pad area interfaces, comprising the steps of:
providing a substrate having an I/O cell area and a bond pad area separated by a trench area; and
forming multiple metal lines over the substrate; the multiple metal lines including a lowermost metal line, lower intermediate metal lines, upper intermediate metal lines and an uppermost metal line;
wherein at least one of the upper intermediate metal lines includes a respective extension portion, that is contiguous with, or separate therefrom, extending at least within the trench area.

2. The method of claim 1, wherein the multiple metal lines are comprised of copper, aluminum, silver or gold.

3. The method of claim 1, wherein the multiple metal lines are comprised of copper.

4. The method of claim 1, including the step of forming respective dielectric material layers separating the multiple metal lines.

5. The method of claim 1, including the step of forming respective dielectric material layers separating the multiple metal lines; the dielectric material layers being comprised of oxide or silicon oxide.

6. The method of claim 1, including the step of forming respective dielectric material layers separating the multiple metal lines; the dielectric material layers being comprised of oxide.

7. The method of claim 1, including the step of forming via structures connecting at least some of the adjacent multiple metal lines within the I/O cell and bond pad areas.

8. The method of claim 1, wherein at least one of the lower intermediate metal lines extends from the I/O cell area, through the trench area and through the bond pad area.

9. The method of claim 1, wherein the lower intermediate metal lines each extend from the I/O cell area, through the trench area and through the bond pad area.

10. The method of claim 1, wherein:
one end of the at least one of the upper intermediate metal lines and the uppermost metal line each extend from the bond pad area, through the trench area and into the I/O cell area; and
the opposing end of the at least one of the upper intermediate metal lines and the uppermost metal line within the I/O cell area are each backed-away from their opposing corresponding extensions to form respective openings therebetween.

11. The method of claim 1, wherein:
at least one of the upper intermediate metal lines extends within only the trench area between the bond pad area and the I/O cell area.

12. The method of claim 1, wherein:
one end of the at least one of the upper intermediate metal lines and the uppermost metal line each extend from the I/O cell area, through the trench area and into the bond pad area; and
the opposing end of the at least one of the upper intermediate metal lines and the uppermost metal line within the bond pad area are each backed-away from their opposing corresponding extensions to form respective openings therebetween.

13. The method of claim 1, wherein:
one end of the at least one of the upper intermediate metal lines and the uppermost metal line each include a respective floating extension within the trench area and each extending into the I/O cell and bond pad areas; and
each opposing end of the at least one of the upper intermediate metal lines and the uppermost metal line within the I/O cell and bond pad areas are each backed-away from their opposing corresponding floating extensions to form respective openings therebetween.

14. A method of forming a layout design for I/O cell area/bond pad area interfaces, comprising the steps of:
providing a substrate having an I/O cell area and a bond pad area separated by a trench area;
forming multiple metal lines over the substrate; the multiple metal lines including a lowermost metal line, lower intermediate metal lines, upper intermediate metal lines and an uppermost metal line; and
forming respective dielectric material layers separating the multiple metal lines;
wherein at least one of the upper intermediate metal lines includes a respective extension portion that is contiguous with, or separate therefrom, extending at least within the trench area.

15. The method of claim 14, wherein the multiple metal lines are comprised of copper, aluminum, silver or gold.

16. The method of claim 14, wherein the multiple metal lines are comprised of copper.

17. The method of claim 14, wherein the dielectric material layers being comprised of oxide or silicon oxide.

18. The method of claim 14, wherein the dielectric material layers being comprised of oxide.

19. The method of claim 14, including the step of forming via structures connecting at least some of the adjacent multiple metal lines within the I/O cell and bond pad areas.

20. The method of claim 14, wherein at least one of the lower intermediate metal lines extends from the I/O cell area, through the trench area and through the bond pad area.

21. The method of claim 14, wherein the lower intermediate metal lines each extend from the I/O cell area, through the trench area and through the bond pad area.

22. The method of claim 14, wherein:
one end of the at least one of the upper intermediate metal lines and the uppermost metal line each extend from the bond pad area, through the trench area and into the I/O cell area; and
the opposing end of the at least one of the upper intermediate metal lines and the uppermost metal line within the I/O cell area are each backed-away from their opposing corresponding extensions to form respective openings therebetween.

23. The method of claim 14, wherein:
at least one of the upper intermediate metal lines extends within only the trench area between the bond pad area and the I/O cell area.

24. The method of claim 14, wherein:
one end of the at least one of the upper intermediate metal lines and the uppermost metal line each extend from the I/O cell area, through the trench area and into the bond pad area; and
the opposing end of the at least one of the upper intermediate metal lines and the uppermost metal line within the bond pad area are each backed-away from their opposing corresponding extensions to form respective openings therebetween.

25. The method of claim 14, wherein:
one end of the at least one of the upper intermediate metal lines and the uppermost metal line each include a respective floating extension within the trench area and each extending into the I/O cell and bond pad areas; and
each opposing end of the at least one of the upper intermediate metal lines and the uppermost metal line within the I/O cell and bond pad areas are each backed-away from their opposing corresponding floating extensions to form respective openings therebetween.

26. A layout design structure for I/O cell area/bond pad area interfaces, comprising:
a substrate having an I/O cell area and a bond pad area separated by a trench area; and
multiple metal lines over the substrate; the multiple metal lines including a lowermost metal line, lower intermediate metal lines, upper intermediate metal lines and an uppermost metal line;
wherein at least one of the upper intermediate metal lines includes a respective extension portion, that is contiguous with, or separate therefrom, extending at least within the trench area.

27. The structure of claim 26, wherein the multiple metal lines are comprised of copper, aluminum, silver or gold.

28. The structure of claim 26, wherein the multiple metal lines are comprised of copper.

29. The structure of claim 26, including respective dielectric material layers separating the multiple metal lines.

30. The structure of claim 26, including respective dielectric material layers separating the multiple metal lines; the dielectric material layers being comprised of oxide or silicon oxide.

31. The structure of claim 26, including respective dielectric material layers separating the multiple metal lines; the dielectric material layers being comprised of oxide.

32. The structure of claim 26, including via structures connecting at least some of the adjacent multiple metal lines within the I/O cell and bond pad areas.

33. The structure of claim 26, wherein at least one of the lower intermediate metal lines extends from the I/O cell area, through the trench area and through the bond pad area.

34. The structure of claim 26, wherein the lower intermediate metal lines each extend from the I/O cell area, through the trench area and through the bond pad area.

35. The structure of claim 26, wherein:
one end of the at least one of the upper intermediate metal lines and the uppermost metal line each extend from the bond pad area, through the trench area and into the I/O cell area; and
the opposing end of the at least one of the upper intermediate metal lines and the uppermost metal line within the I/O cell area are each backed-away from their opposing corresponding extensions to form respective openings therebetween.

36. The structure of claim 26, wherein:
one end of the at least one of the upper intermediate metal lines and the uppermost metal line each extend from the I/O cell area, through the trench area and into the bond pad area; and
the opposing end of the at least one of the upper intermediate metal lines and the uppermost metal line within the bond pad area are each backed-away from their opposing corresponding extensions to form respective openings therebetween.

37. The structure of claim 26, wherein:
one end of the at least one of the upper intermediate metal lines and the uppermost metal line each include a respective floating extension within the trench area and each extending into the I/O cell and bond pad areas; and
each opposing end of the at least one of the upper intermediate metal lines and the uppermost metal line within the I/O cell and bond pad areas are each backed-away from their opposing corresponding floating extensions to form respective openings therebetween.

38. The method of claim 26, wherein:
at least one of the upper intermediate metal lines extends within only the trench area between the bond pad area and the I/O cell area.
